(19) United States
(12) Patent Application Publication
(10) Pub. No.: US 2017/0347444 A1
(43) Pub. Date: Nov. 30, 2017

(54) MANUFACTURING METHOD OF CURVED CIRCUIT BOARD AND ELECTRONIC PRODUCT

(71) Applicant: MOORETEC CO.,LTD., Hsinchu City (TW)

(72) Inventors: YU-MIN LIN, YILAN COUNTY (TW); CHIA-PIN WANG, NEW TAIPEI CITY (TW); CHIA-CHING SUNG, MIAOLI COUNTY (TW); NA LU, HSINCHU CITY (TW)

(21) Appl. No.: 15/164,847

(22) Filed: May 25, 2016

(51) Int. Cl. H05K 1/02; H05K 3/00; H05K 3/46; H05K 3/18; H05K 1/03

(52) U.S. Cl. CPC H05K 1/028; H05K 3/185; H05K 1/0393; H05K 3/4635; H05K 1/0353; H05K 3/0014; H05K 2201/041; H05K 2201/057

(57) ABSTRACT

The present invention provides a manufacturing method of a curved circuit board which includes the following steps. The first step is to provide a flexible substrate. The next step is to form a patterned catalyst layer on the flexible substrate. The next step is to deposit metal on the patterned catalyst layer by electroless plating to form a wiring substrate, wherein the wiring substrate includes a planar wiring structure. The last step is to place the wiring substrate into a mold having a molding surface with a three-dimensional design, and then execute a heating process to shape the planar wiring structure to a three-dimensional wiring structure, wherein the heated wiring substrate is laminated to the molding surface of the mold. The present invention further provides an electronic product using the curved circuit board.

### BACKGROUND OF THE INVENTION

### 1. Field of the Invention

The instant disclosure relates to a manufacturing method of circuit board; in particular, to a manufacturing method of curved circuit board, and an electronic product using the curved circuit board.

### 2. Description of Related Art

Population densities of printed circuit boards have increased with the flourishing development of technology and information. Circuit substrates have thus become more and more important in consumer electronic products and their accessories. In recent years, electronic products follow the trend of diversity and high performance, and miniaturization is a basic requirement of product design. Therefore, electronic products need to be shaped from a planar shape into a three-dimensional (3D) shape.

The production of curved circuit boards is one key point of manufacturing 3D electronic products. However, there is a lack of a common technology having the advantages of low cost and easy processing to shape the planar circuit into a non-planar 3D shape. That is, when compared to the planar circuit, the 3D circuit is subject to many limitations when processing, such that process difficulties and production cost cannot be reduced.

Although the planar circuit can be shaped into a non-planar three-dimensional shape by edge cutting or double sided tape, it is not practical in consideration of cost per processing time. There is an urgent need for a common technology to reduce process difficulties and production cost of the production of the 3D circuit.

### SUMMARY OF THE INVENTION

The object of the instant disclosure is to provide a manufacturing method of a curved circuit board which not only assists in reducing processing difficulties and production cost, but also acts to manufacture a curved circuit board which can meet the requirements of various electronic products such as smartphone, tablet computer, and electronic paper.

In order to achieve the aforementioned objects, according to an embodiment of the instant disclosure, the manufacturing method comprises the following steps: providing a flexible substrate; forming a patterned catalyst layer on the flexible substrate; depositing metal on the patterned catalyst layer by electroless plating to form a wiring substrate, wherein the wiring substrate includes a planar wiring structure; and placing the wiring substrate into a mold having a molding surface with a three-dimensional design, and then executing a heating process to shape the planar wiring structure to a three-dimensional wiring structure, wherein the heated wiring substrate is laminated to the molding surface of the mold.

In order to achieve the aforementioned objects, according to another embodiment of the instant disclosure, the manufacturing method comprises the following steps: providing a flexible substrate; forming a patterned catalyst layer on the flexible substrate to obtain a planar composite structure; placing the planar composite structure into a mold having a molding surface with a three-dimensional design, and then executing a heating process to shape the planar composite structure to a three-dimensional composite structure, wherein the three-dimensional composite structure is laminated to the molding surface of the mold; and depositing metal on the patterned catalyst layer of the three-dimensional composite structure by electroless plating to form a three-dimensional wiring structure.

Another object of the instant disclosure is to provide an electronic product using a curved circuit board, characterized in that the curved circuit board comprises a three-dimensional flexible substrate, a patterned catalyst layer, and a three-dimensional wiring structure. The patterned catalyst layer is conformally formed on the three-dimensional flexible substrate. The three-dimensional wiring structure is formed only on the patterned catalyst layer. The surfaces of the three-dimensional flexible substrate, the patterned catalyst layer and the three-dimensional wiring structure have the same three-dimensional design.

The benefits of the present invention include: by executing the process of producing a three-dimensional composite structure and then forming a circuit pattern on the three-dimensional composite structure by electroless plating, or by executing the process of producing a planar circuit board with a circuit pattern by electroless plating and then shaping the planar circuit board into a three-dimensional shape, the manufacturing method not only can reduce processing difficulties, but also can accurately control the curvature of the resulting curved circuit board to meet the quality requirements.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 is a flow diagram illustrating a manufacturing method of curved circuit board according to the first embodiment of the present invention;

FIGS. 2A to 7 are schematic diagrams showing respectively steps performed in the manufacturing method of curved circuit board according to the first embodiment of the present invention;

FIG. 8 is a flow diagram illustrating a manufacturing method of curved circuit board according to the second embodiment of the present invention;

FIGS. 9A to 12 are schematic diagrams showing respectively steps performed in the manufacturing method of curved circuit board according to the second embodiment of the present invention.

FIG. 13 is a cross-sectional, schematic diagram of a curved circuit board of the present invention;

FIG. 14A is a schematic diagram of a curved circuit board of the present invention; and

FIG. 14B is an enlarged diagrams showing the part A of FIG. 14A.

### DETAILED DESCRIPTION OF THE PREFERRED EMBODIMENTS

Reference will now be made in detail to the exemplary embodiments of the present disclosure, examples of which are illustrated in the accompanying drawings. Wherever possible, the same reference numbers are used in the drawings and the description to refer to the same or like parts.

Notably, the terms first, second, third, etc., may be used herein to describe various elements or signals, but these signals should not be affected by such elements or terms. Such terminology is used to distinguish one element from another or a signal with another signal. Further, the term “or” as used herein in the case may include any one or combinations of the associated listed items.

### First Embodiment

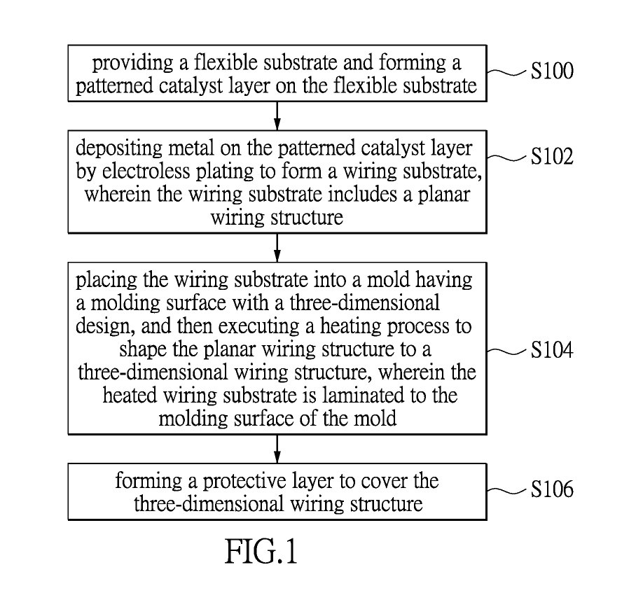

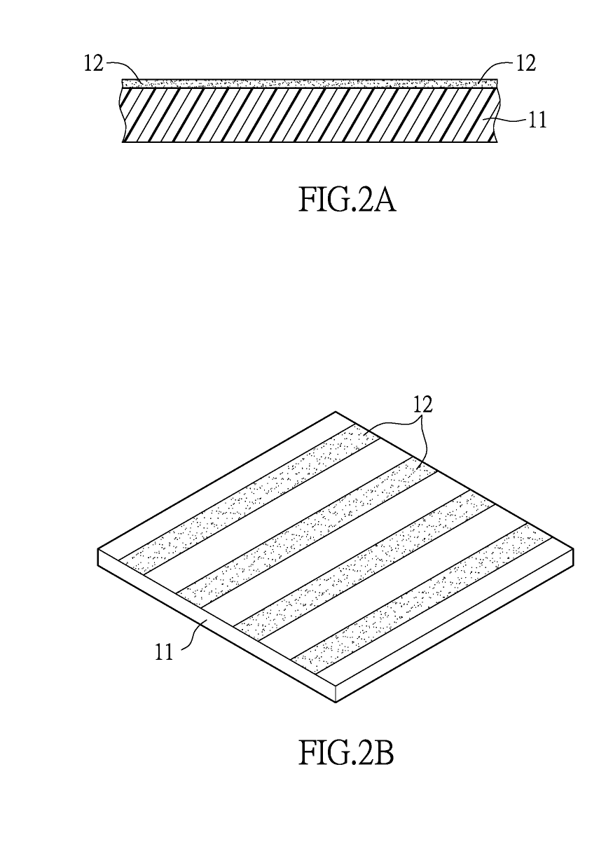

Please refer to FIG. 1, and refer to FIGS. 2A to 6B as well. FIG. 1 is a flow diagram illustrating a manufacturing method of curved circuit board according to the first embodiment of the present invention. FIGS. 2A to 6B are schematic diagrams showing respectively steps performed in the manufacturing method. The manufacturing method is adapted for manufacturing a circuit substrate with a simple arc curved surface, as shown in FIG. 1, comprising steps of: providing a flexible substrate and forming a patterned catalyst layer on the flexible substrate (S100); depositing metal on the patterned catalyst layer by electroless plating to form a wiring substrate, wherein the wiring substrate includes a planar wiring structure (S102); and placing the wiring substrate into a mold having a molding surface with a three-dimensional design, and then executing a heating process to shape the planar wiring structure to a three-dimensional wiring structure, wherein the heated wiring substrate is laminated to the molding surface of the mold (S104).

In the step S100, referring to FIGS. 2A and 2B, the planar flexible substrate 11 can be used as a case body or a casing assembly for an electronic product (e.g., portable device). The planar flexible substrate 11 can be made from a thermoset material which is normally a solid at room temperature and begins to soften when heated to a predetermined temperature. Specific examples of the thermoset material include polycarbonate, polypropylene, acrylonitrile butadiene styrene, polyethylene terephthalate, and polyimide.

The patterned catalyst layer 12 is printed on the planar flexible substrate 11 according to a predetermined circuit pattern. Specifically, a screen printing plate (not shown) is disposed above the planar flexible substrate 11, wherein the screen printing plate has a hollow section in relation to the design of the circuit pattern. Next, a resin-based catalyst material is pushed through the screen printing plate by scraping onto the surface of the planar flexible substrate 11, and then curing thermally. Preferably, the thickness of the patterned catalyst layer 12 is between 0.1 μm to 30 μm.

For the instant embodiment, the patterned catalyst layer 12 includes a catalyst and a curing agent, wherein the content of the curing agent is about 1% to about 10% by weight. The catalyst can be used for electroless metal deposition and can be changed in relation to the desired metal. For example, the catalyst can be selected from the group consisting of palladium-based catalysts, silver-based catalysts, carbon-based catalysts, and combinations thereof. The used catalyst is suitably selected from palladium-based catalysts such as palladium sulfate, palladium chloride, diammine dichloropalladium (II), tetraammine dichloropalladium(II), and diaminedinitritopalladium (II). Specific examples of the curing agent include an aliphatic amine curing agent, cyclic aliphatic amine curing agent, polyamide curing agent, aromatic amine curing agent, acid anhydride type curing agent, lewis acid type curing agent, and imidazole type curing agent.

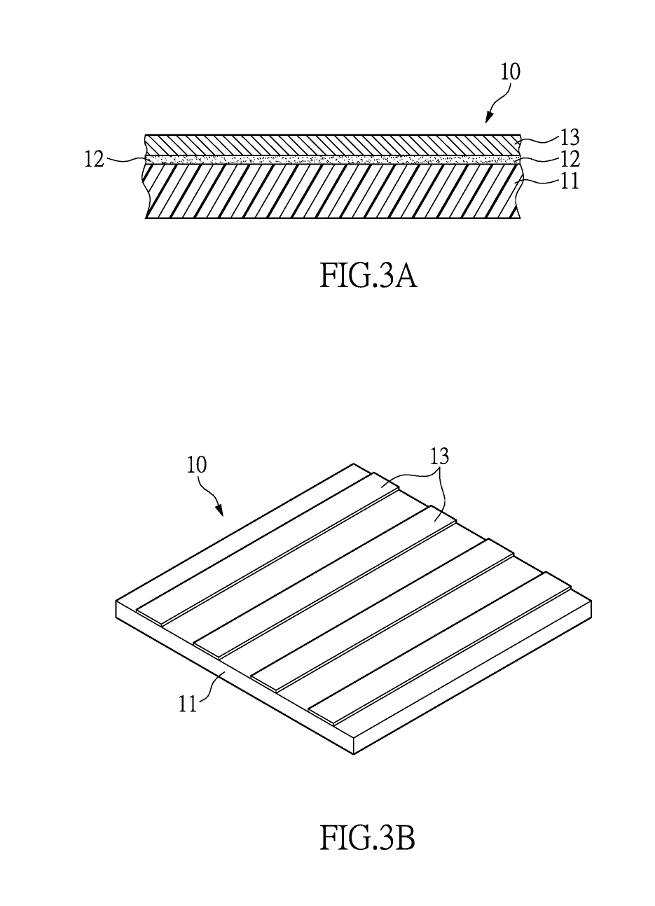

In the step S102, referring to FIGS. 3A and 3B, the planar flexible substrate 11 having the catalytic circuit pattern thereon is immersed in an electroless plating bath containing the desired metal ions. The desired metal ions are then reduced onto the surface of the patterned catalyst layer 12 by catalysis after reaction times of about 5 minutes to form a planar wiring structure 13, and a wiring substrate 10 is thus obtained.

For the instant embodiment, the planar wiring structure 13 can be made from metals having better conductivity such as gold, silver, copper, nickel, aluminum, and chromium. There is no particular restriction as to the material for the planar wiring structure 13. Preferably, an electroless copper plating process is used for producing the wiring substrate 10, wherein the processing time is between 5 and 500 minutes. However, the processing time can be adjusted according to the desired thickness of the planar wiring structure 13. Moreover, the electroless plating bath used can be a basic plating bath having a pH-value within the range 9 to 14 such as a plating bath including copper chloride (CuCl₂), and the temperature of which can range from about 20° C. to about 100° C.

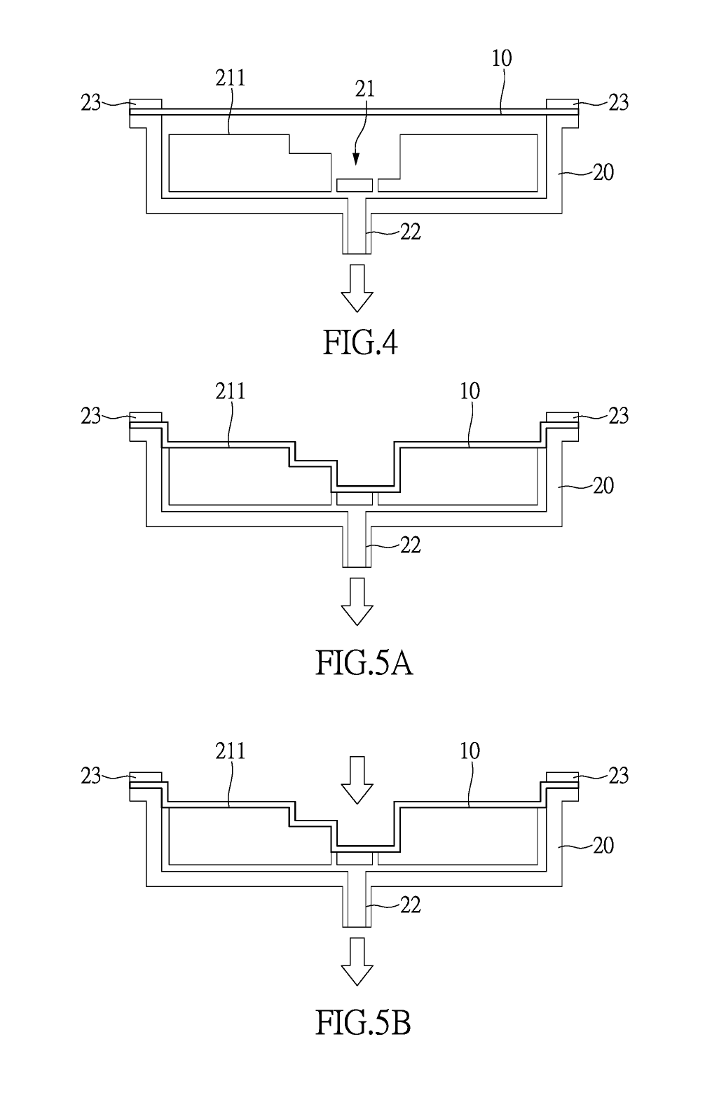

In the step S104, referring to FIGS. 4 to 5B, the mold 20 has a mold cavity 21 and a vent hole 22 at the bottom thereof. The mold cavity 21 is formed with a molding surface 211 having a three-dimensional design which is in relation to the structure of the final product. Thereby, the wiring substrate 10 can be held on the mold 20 by at least one pressing member 23 and then heated by a heater (not shown) to shape the planar wiring structure 13 to a three-dimensional wiring structure 13′. Preferably, for assisting the lamination of the wiring substrate 10 on the molding surface 211 of the mold 20, a suction device (not shown) can be used to apply a negative pressure to the wiring substrate 10 along a direction of moving close to/further away from the molding surface 211 through the vent hole 23 when heating. In various embodiments, a blowing device (not shown) and a suction device can be used to apply a negative pressure and a positive pressure concurrently to the wiring substrate 10 along a direction of moving close to/further away from the molding surface 211 of the mold 20.

For the instant embodiment, the mold 20 can be placed directly into the heater or fixed at a suitable position in the heater. The mold 20 can be made of metal, ceramic, or any high temperature resistant material, used to heat the wiring substrate 10 to a temperature within the range 150° C. to 600° C. There is no particular restriction regarding the heating means of the mold 20.

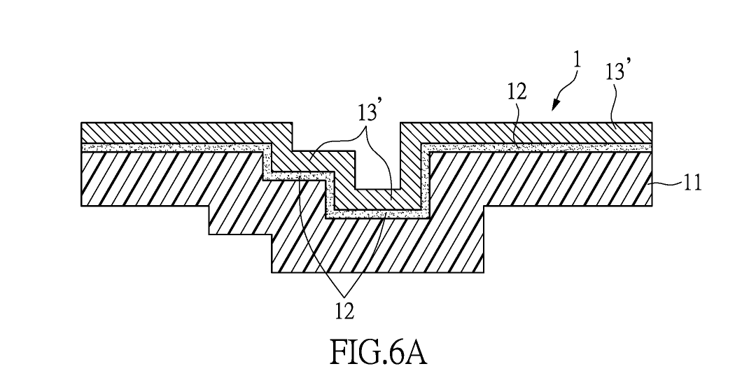

Referring to FIGS. 6A to 6B, after the step S104, the planar wiring structure 13 can be shaped to the three-dimensional wiring structure 13′, and have a thickness between 0.1 μm to 30 μm. Please note that the three-dimensional wiring structure 13′ is formed with a curvature having predetermined degrees which are designed in relation to the structure of the final product. For example, the three-dimensional wiring structure 13′ can be configured for a single axis configuration, a dual axis configuration, or a multiple axis configuration.

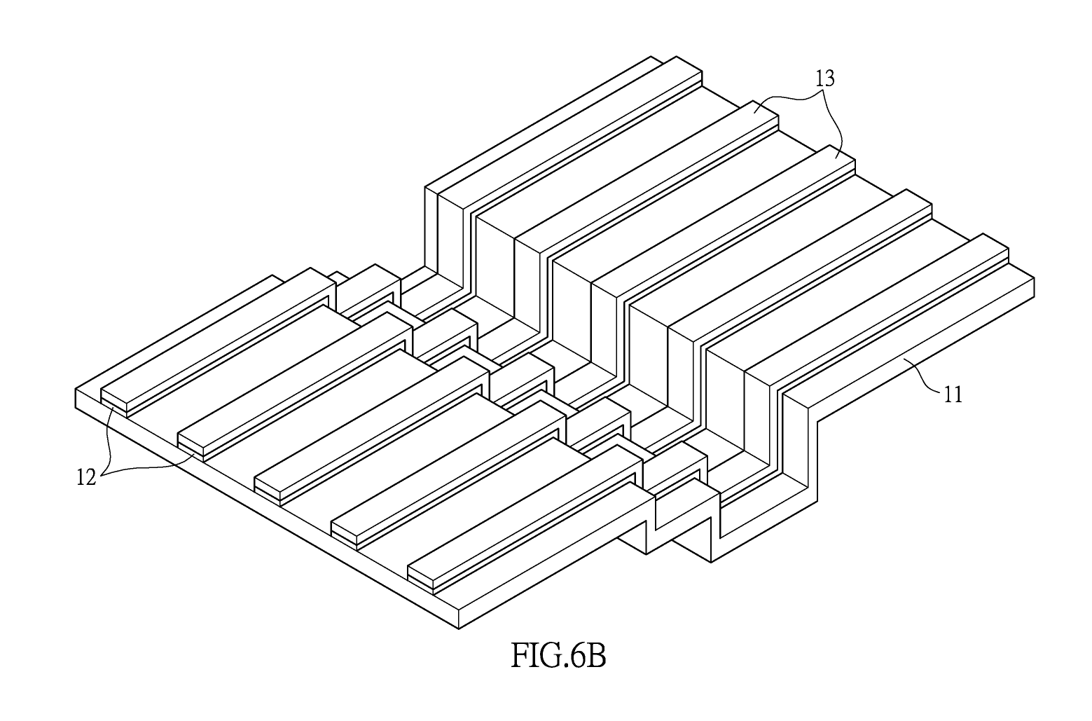

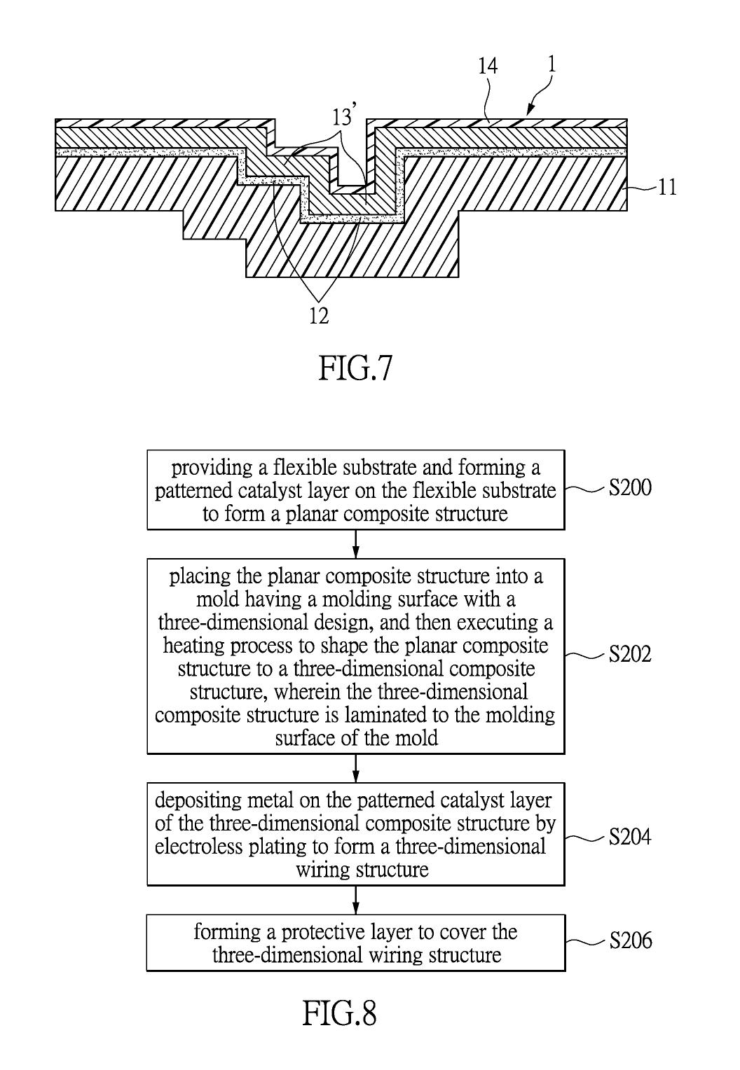

Referring to FIG. 7, the manufacturing method can further comprise a step of forming a protective layer 14 to cover the three-dimensional wiring structure 13′ (S106). For the instant embodiment, the protective layer 14 can be formed by plastic injection molding and its material may be the same as or different from the planar flexible substrate 11. For example, the protective layer 14 can be made from polymethyl methacrylate (PMMA), polyether sulfone (PES), cellulose esters, polyvinyl chloride (PVC), benzocyclobutene (BCB), and acrylic resin.

### Second Embodiment

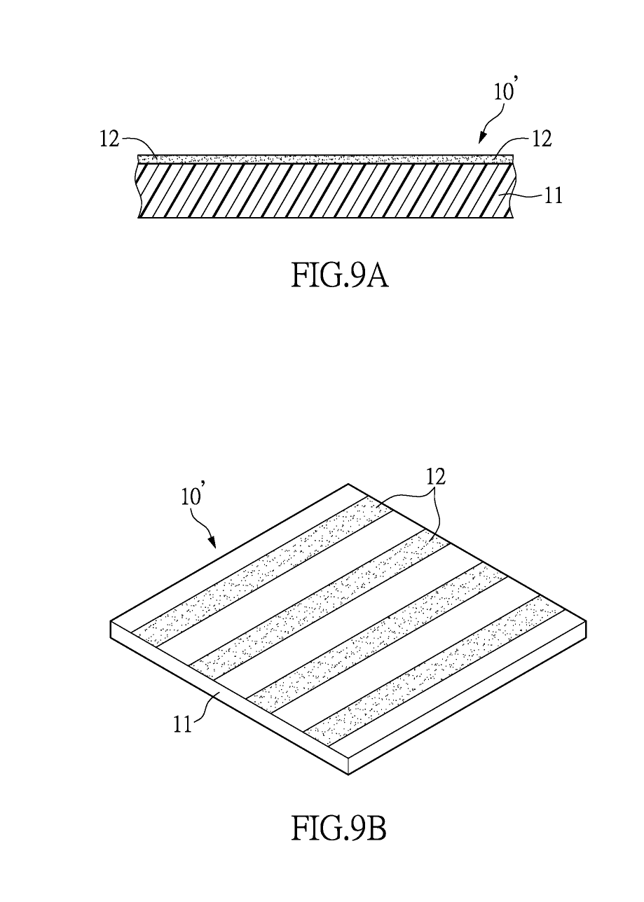

Please refer to FIG. 8, and refer to FIGS. 9A to 12 as well. FIG. 8 is a flow diagram illustrating a manufacturing method of a curved circuit board according to the second embodiment of the present invention. FIGS. 9A to 12 are schematic diagrams showing respectively steps performed in the manufacturing method.

Please note that the feature of the second embodiment for manufacturing a curved circuit board is to produce a three-dimensional composite structure and then to form a circuit pattern on the three-dimensional composite structure by electroless plating. Comparing to the first embodiment, the feature of which is to produce a planar circuit board with a circuit pattern by electroless plating and then to shape the planar circuit board to a curved circuit board, the manufacturing method of the second embodiment is adapted for manufacturing a circuit substrate with a complex curved surface.

Referring to FIGS. 9A and 9B, the first step S200 of the manufacturing method of the second embodiment is to provide a planar flexible substrate 11 and forming a patterned catalyst layer 12 on the planar flexible substrate 11 to obtain a planar composite structure 10′. The structural features of the planar flexible substrate 11 and the patterned catalyst layer 12 and methods of making the same are described in the first embodiment, and therefore these will not be discussed in more detail here.

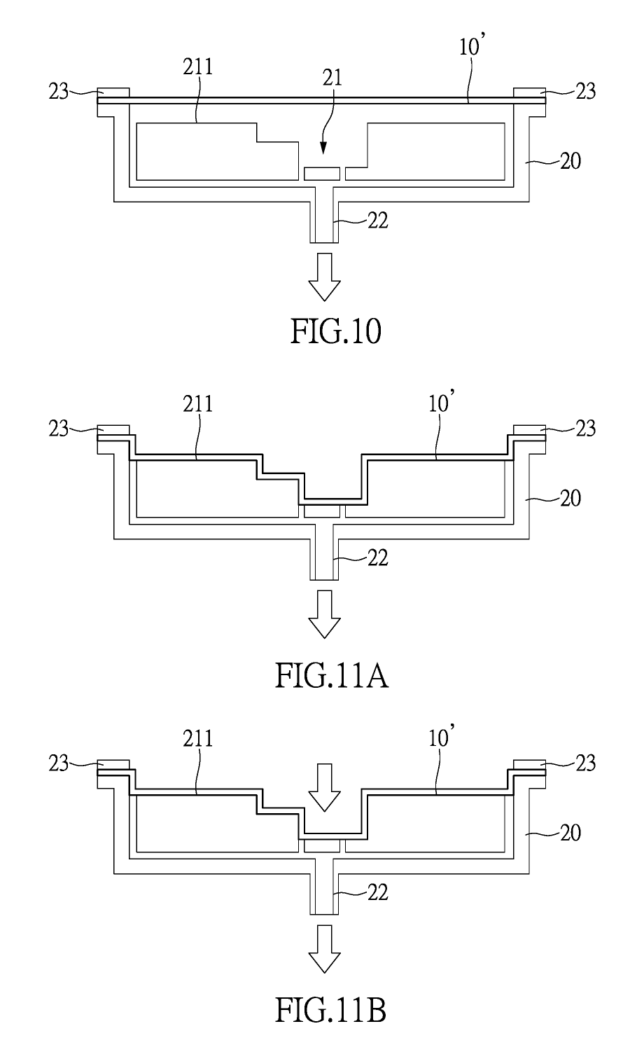

Referring to FIGS. 10, 11A and 11B, the next step S202 is to place the planar composite structure 10′ into a mold 20 having a molding surface 211 with a three-dimensional design, and then to execute a heating process to shape the planar composite structure 10′ to a three-dimensional composite structure, wherein the three-dimensional composite structure is laminated to the molding surface 211 of the mold 20. For the instant embodiment, the planar composite structure 10′ can be held on the mold 20 by at least one pressing member 23 and then heated by a heater (not shown).

Preferably, for assisting the lamination of the three-dimensional composite structure on the molding surface 211 of the mold 20, a suction device (not shown) can be used to apply a negative pressure to the planar composite structure 10′ along a direction of moving close to/further away from the molding surface 211 through the vent hole 22. In various embodiments, due to an increase in thickness, a blowing device (not shown) and a suction device can be used to apply a negative pressure and a positive pressure concurrently to the planar composite structure 10′ along a direction of moving close to/further away from the molding surface 211 of the mold 20.

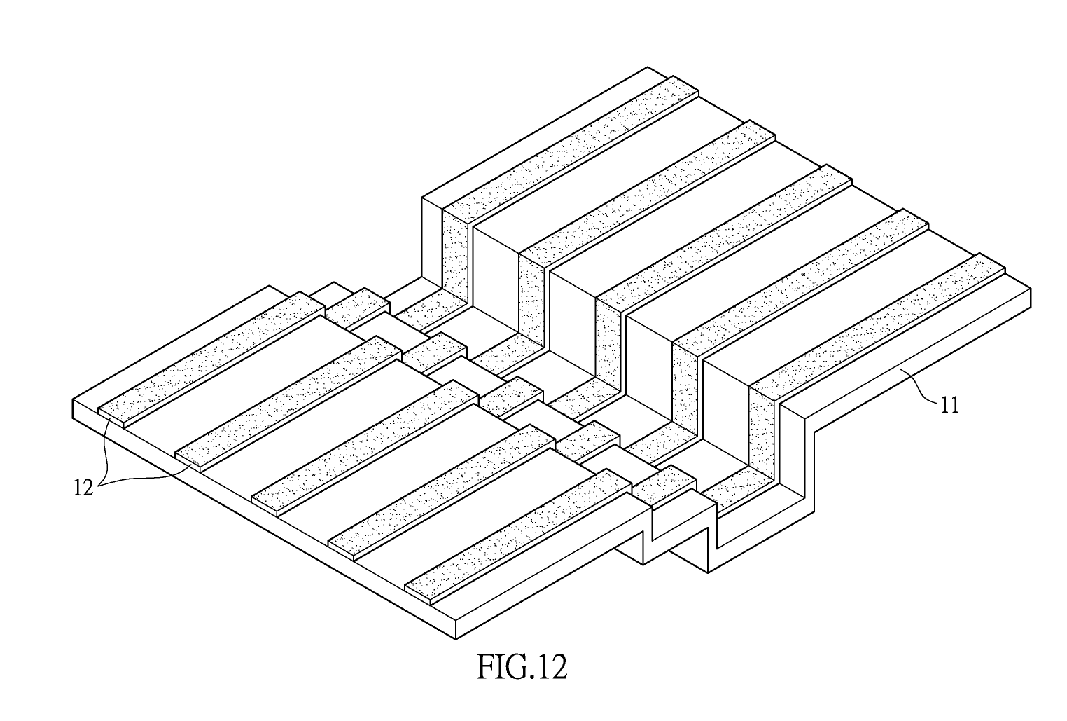

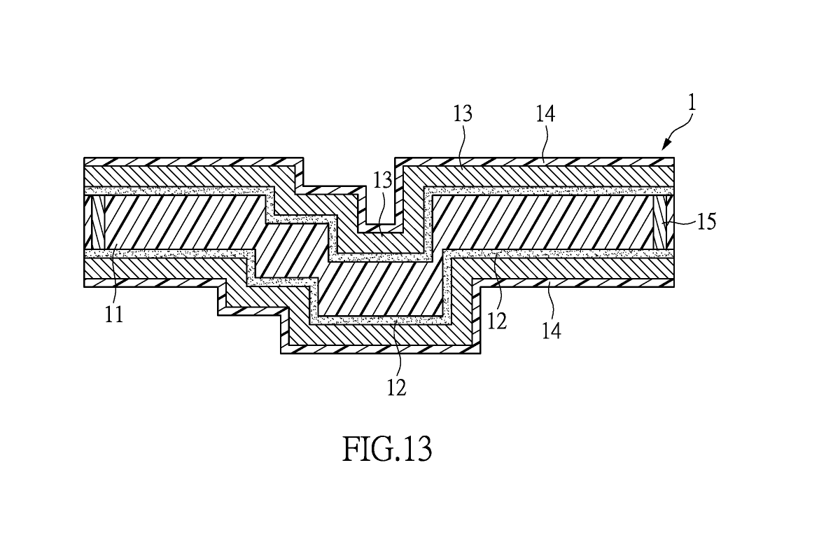

Referring to FIGS. 12 and 13, the next step S204 is to deposit metal on the patterned catalyst layer 12 of the three-dimensional composite structure by electroless plating to form a three-dimensional wiring structure 13′. The structural features of the three-dimensional wiring structure 13′ and the operating conditions of the electroless plating process are described in the first embodiment, and therefore these will not be discussed in more detail here.

The manufacturing method can further comprise a step of forming a protective layer 14 to cover the three-dimensional wiring structure 13′ (S206). The structural features of the protective layer 14 and methods of making the same are described in the first embodiment, and therefore these will not be discussed in more detail here.

Please note that the manufacturing methods of both the first and second embodiments can be used in manufacture of single-sided or double-sided curved circuit board 1. Specifically, the resulting single-sided curved circuit board 1, as shown in FIG. 7, includes a three-dimensional flexible substrate 11′, a patterned catalyst layer 12, and a three-dimensional wiring structure 13′. The patterned catalyst layer 12 is conformally formed on the three-dimensional flexible substrate 11′. The three-dimensional wiring structure 13′ is formed only on the patterned catalyst layer 12. The surfaces of the three-dimensional flexible substrate 11′, the patterned catalyst layer 12 and the three-dimensional wiring structure 13′ have the same three-dimensional design.

The resulting double-sided curved circuit board 1 includes a three-dimensional flexible substrate 11′, two patterned catalyst layers 12, and two three-dimensional wiring structures 13′. The three-dimensional flexible substrate 11′ includes at least one conductive structure 15 embedded therein. The two patterned catalyst layers 12 are respectively formed on the two opposite surfaces of the three-dimensional flexible substrate 11′. The two three-dimensional wiring structures 13′ are respectively formed on the two patterned catalyst layers 12, and can be electrically connected to each other by the at least one conductive structure 15. The three-dimensional flexible substrate 11′, the two patterned catalyst layer 12 and the two three-dimensional wiring structures 13′ have the same three-dimensional configuration. In other words, the surfaces of the three-dimensional flexible substrate 11′, the two patterned catalyst layer 12 and the two three-dimensional wiring structures 13′ have the same three-dimensional design.

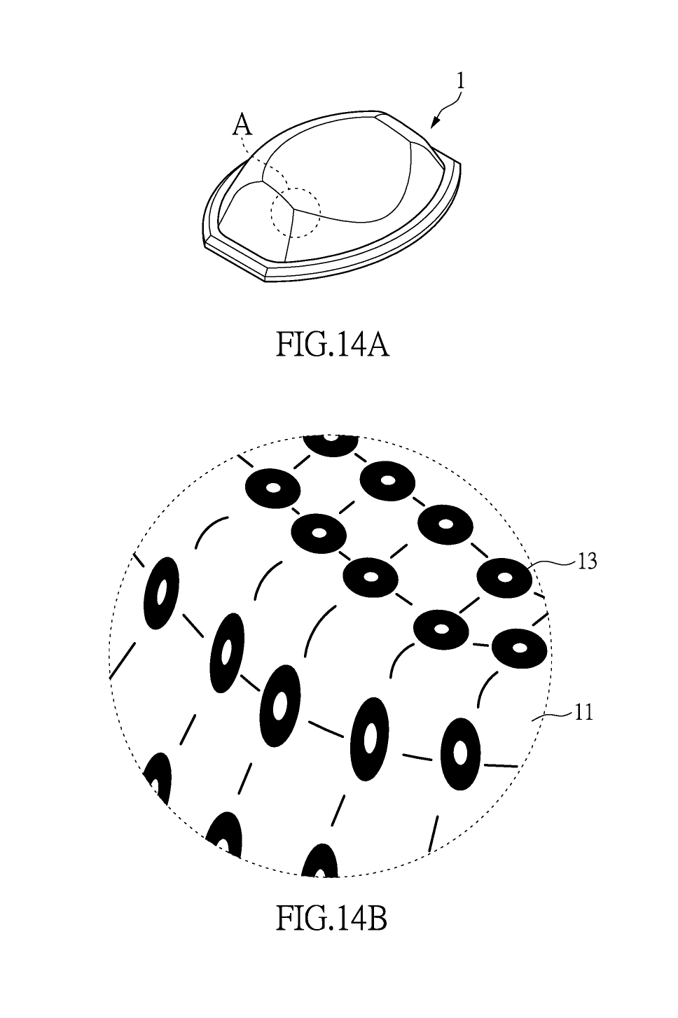

Referring to FIGS. 14A and 14B, please note that the curvature type and the circuit pattern of the curved circuit board 1 can be designed in relation to the structure of the final product. Moreover, the three-dimensional wiring structures 13′ of the resulting curved circuit board 1 can exhibit good bending resistance performance and be can be tightly combined to the three-dimensional flexible substrate 11′ without breaking.

To sum up, by executing the process of producing a three-dimensional composite structure and then forming a circuit pattern on the three-dimensional composite structure by electroless plating, or by executing the process of producing a planar circuit board with a circuit pattern by electroless plating and then shaping the planar circuit board into a three-dimensional shape, the manufacturing method not only can reduce processing difficulties, but also can accurately control the curvature of the resulting curved circuit board to meet the quality requirements.

Moreover, the manufacturing method can solve the lack of a common technology for shaping the planar circuit pattern into a three-dimensional shape and the problem of difficulty in operation. The resulting curved circuit board can meet the requirements of electronic, photoelectronic, and semiconductor industries.

In addition, the manufacturing method can be implemented in any known apparatus, and thus the production costs can be reduced. The manufacturing method can also be with the roll-to-roll (r2r) process for large-scale production.

The descriptions illustrated supra set forth simply the preferred embodiments of the instant disclosure; however, the characteristics of the instant disclosure are by no means restricted thereto. All changes, alterations, or modifications conveniently considered by those skilled in the art are deemed to be encompassed within the scope of the instant disclosure delineated by the following claims.

What is claimed is:

1. A manufacturing method of curved circuit board, comprising the following steps:
providing a flexible substrate;
forming a patterned catalyst layer on the flexible substrate;
depositing metal on the patterned catalyst layer by electroless plating to form a wiring substrate, wherein the wiring substrate includes a planar wiring structure; and
placing the wiring substrate into a mold having a molding surface with a three-dimensional design, and then executing a heating process to shape the planar wiring structure to a three-dimensional wiring structure, wherein the heated wiring substrate is laminated to the molding surface of the mold.

2. The manufacturing method according to claim 1, after the step of placing the wiring substrate into the mold, further comprising: forming a protective layer to cover the three-dimensional wiring structure.

3. The manufacturing method according to claim 1, wherein the step of executing the heating process to shape the planar wiring structure to the three-dimensional wiring structure further comprises: heating the wiring substrate to a temperature within the range 150° C. to 600° C. and applying a negative pressure to the wiring substrate along a direction of moving close to/further away from the molding surface of the mold.

4. The manufacturing method according to claim 1, wherein the step of executing the heating process to shape the planar wiring structure to the three-dimensional wiring structure further comprises: heating the wiring substrate to a temperature within the range 150° C. to 600° C. and applying a negative pressure and a positive pressure concurrently to the wiring substrate along a direction of moving close to/further away from the molding surface of the mold.

5. The manufacturing method according to claim 1, wherein the patterned catalyst layer includes a curing agent and a palladium catalyst, and the thickness of the patterned catalyst layer is between 0.1 μm to 30 μm.

6. The manufacturing method according to claim 5, wherein the curing agent is selected from a group consisting of aliphatic amine curing agent, cyclic aliphatic amine curing agent, polyamide curing agent, aromatic amine curing agent, acid anhydride-type curing agent, lewis acid type curing agent, imidazole type curing agent, and combinations thereof.

7. The manufacturing method according to claim 1, wherein the flexible substrate is made from polycarbonate, polypropylene, acrylonitrile butadiene styrene, polyethylene terephthalate, or polyimide.

8. A manufacturing method of curved circuit board, comprising the following steps:
providing a flexible substrate;
forming a patterned catalyst layer on the flexible substrate to obtain a planar composite structure;
placing the planar composite structure into a mold having a molding surface with a three-dimensional design, and then executing a heating process to shape the planar composite structure to a three-dimensional composite structure, wherein the three-dimensional composite structure is laminated to the molding surface of the mold; and
depositing metal on the patterned catalyst layer of the three-dimensional composite structure by electroless plating to form a three-dimensional wiring structure.

9. The manufacturing method according to claim 8, after the step of placing the wiring substrate into the mold, further comprising:
forming a protective layer to cover the three-dimensional wiring structure.

10. The manufacturing method according to claim 8, wherein the step of executing the heating process to shape the planar composite structure to a three-dimensional composite structure further comprises: heating the planar composite structure to a temperature within the range 150° C. to 600° C. and applying a negative pressure to the planar composite structure along a direction of moving close to/further away from the molding surface of the mold.

11. The manufacturing method according to claim 8, wherein the step of executing the heating process to shape the planar composite structure to a three-dimensional composite structure further comprises: heating the planar composite structure to a temperature within the range 150° C. to 600° C. and applying a negative pressure and a positive pressure concurrently to the planar composite structure along a direction of moving close to/further away from the molding surface of the mold.

12. The manufacturing method according to claim 8, wherein the patterned catalyst layer includes a curing agent and a palladium catalyst, and the thickness of the patterned catalyst layer is between 0.1 μm to 30 μm.

13. The manufacturing method according to claim 12, wherein the curing agent is selected from the group consisting of aliphatic amine curing agent, cyclic aliphatic amine curing agent, polyamide curing agent, aromatic amine curing agent, acid anhydride-type curing agent, lewis acid type curing agent, imidazole type curing agent, and combinations thereof.

14. The manufacturing method according to claim 8, wherein the flexible substrate is made from polycarbonate, polypropylene, acrylonitrile butadiene styrene, polyethylene terephthalate, or polyimide.

15. An electronic product using a curved circuit board, characterized in that the curved circuit board comprises:
a three-dimensional flexible substrate;
a patterned catalyst layer conformally formed on the three-dimensional flexible substrate; and
a three-dimensional wiring structure formed only on the patterned catalyst layer;
wherein the surfaces of the three-dimensional flexible substrate, the patterned catalyst layer and the three-dimensional wiring structure have the same three-dimensional design.

16. The electronic product according to claim 15, wherein the three-dimensional flexible substrate is a plastic substrate.

17. The electronic product according to claim 16, wherein the plastic substrate is made from polycarbonate, polypropylene, acrylonitrile butadiene styrene, polyethylene terephthalate, or polyimide.

18. The electronic product according to claim 15, wherein the thickness of the patterned catalyst layer is between 0.1 μm to 30 μm, and the thickness of the three-dimensional wiring structure is between 0.1 μm to 30 μm.

19. The electronic product according to claim 15, further comprising a protective layer conformally formed on the three-dimensional wiring structure.
